(19) United States
(12) Patent Application Publication
(10) Pub. No.: US 2025/0180610 A1
(43) Pub. Date: Jun. 5, 2025

(54) PORTABLE VOLTAGE DETECTOR AND SYSTEM FOR WARNING OF VOLTAGE HAZARDS

(71) Applicant: DEHN SE, Neumarkt i.d.OPf. (DE)

(72) Inventors: Michael Stehle, Postbauer-Heng (DE); Andreas Waigel, Alfeld (DE)

(21) Appl. No.: 18/842,240

(22) PCT Filed: Mar. 3, 2023
(86) PCT No.: PCT/EP2023/055470

§ 371 Date: Oct. 4, 2024

(30) Foreign Application Priority Data
Mar. 3, 2022 (DE) 10 2022 105 066.1

(51) Int. Cl. G01R 19/155; G01R 19/25; G01R 31/319

(52) U.S. Cl. CPC G01R 19/155; G01R 19/2513; G01R 31/31914

(57) ABSTRACT

A portable voltage detector (100) comprises a housing (106), a sensor circuit accommodated in the housing (106) for detecting electric fields (501) within a detection range of the portable voltage detector (100), an evaluation unit accommodated in the housing (106) for evaluating the detected electric fields, the evaluation unit being connected to the sensor circuit. A warning device (104) connected to the evaluation unit is set up to output a warning signal if the strength of an electric field (501) detected by the sensor circuit reaches or exceeds a warning threshold. A wireless communication interface of the portable voltage detector (100) connected to the evaluation unit is configured to receive a setting signal to determine the warning threshold. A voltage source connected to the sensor circuit and the communication interface is configured to be charged by means of a unit for inductive charging.

The invention relates to a portable voltage detector for detecting electric fields in the vicinity of current-carrying electric lines, and to a system for warning of voltage hazards.

Portable voltage detectors serve to warn a user before they approach current-carrying electric lines, so that the user can avoid contact with the electric lines or maintain a necessary safety distance. In the field of technical work on electric lines and systems, portable voltage detectors thus provide an additional way to increase occupational safety.

The functional principle of such voltage detectors is based on the fact that the electric field of a current-carrying line generates an electric displacement current in a sensor element of the voltage detector, which can be measured and evaluated. If it is determined that a previously determined warning threshold is exceeded, the voltage detector can warn its user, for example by means of an acoustic warning.

The critical factor for the successful use of portable voltage detectors is therefore the determined warning threshold, i.e. how sensitive the voltage detector is set.

A lower warning threshold ensures that the voltage detector triggers even when the distance to the current-carrying line is greater, while the voltage on the current-carrying line remains the same. Though a high level of safety is thus provided, it may also cause the portable voltage detector to trigger excessively often when working, in particular with or near medium and high-voltage lines.

Here and in the following, “high voltage” refers to a voltage of at least 1 kV AC, whereas “low voltage” refers to a voltage below 1 kV AC.

Furthermore, the “high voltage” range is usually subdivided into ranges, namely the medium voltage range (up to 60 kV), the high voltage range (from 60 kV to 220 kV) and the extra-high voltage range (from 220 kV).

However, if a higher warning threshold is used, the user is given more personal responsibility, since a warning is output by the portable voltage detector only at a significantly shorter distance to the current-carrying line when the voltage remains the same.

In the case of laypersons or electrotechnically only instructed persons, a full assessment of the danger emanating from current-carrying lines cannot be assumed. Therefore, a portable voltage detector for this user group must have the highest possible sensitivity. In addition, the operation of the voltage detector should be as easy as possible to avoid operating errors. Examples of persons from such a user group are members of the public hazard defense such as the fire brigade, medical service, police and technical relief service, as well as construction workers and installers in the fields of gas supply, water supply and/or water disposal.

On the other hand, it can be assumed that skilled electricians have an increased awareness and sufficient ability to assess the danger emanating from current-carrying electric lines due to their education. For this user group, the portable voltage detector serves only as an additional warning device. However, the challenge here is that when working on complex systems of electric lines, only individual branches may be switched to a voltage-free state, so that work has to be carried out at a comparatively close distance to still current-carrying electric lines. To avoid a permanent triggering of the portable voltage detector, it must therefore be possible for these users to adjust the warning threshold on site and depending on the situation.

Until now, it has been common practice to provide different voltage detectors for these different requirement profiles, which however results in high procurement, storage and maintenance costs.

A further challenge in the design of portable voltage detectors is their power supply. This is usually provided by built-in primary or secondary cells. Primary cells can only be used once and are not desirable for ecological reasons. Secondary cells can be recharged. To this end, it is known to provide a charging connection in the voltage detector housing, for example a mini or micro USB interface.

The disadvantage of this solution is that an opening must be made in the housing of the voltage detector, allowing dirt and moisture to enter. This disadvantage is further increased by the fact that work on current-carrying lines, in particular in the case of high-voltage systems, often has to be carried out in harsh environments and also in bad weather conditions. In this case, additional sealing of the charging connection must be provided, which significantly increases the design effort. Furthermore, it is cumbersome for the user to have to connect charging cables while wearing the protective gloves necessary for the work.

The object of the invention is to provide a portable voltage detector which is suitable for a wide range of user groups, is easy to use and can reliably warn against current-carrying electric lines.

According to the invention, the object is achieved by a portable voltage detector comprising a housing, a sensor circuit accommodated in the housing for detecting electric fields within a detection range of the portable voltage detector, and an evaluation unit accommodated in the housing for evaluating the detected electric fields. The evaluation unit is connected to the sensor circuit. Furthermore, the evaluation unit is connected to a warning device which is set up to output a warning signal if the strength of an electric field detected by the sensor circuit reaches or exceeds a warning threshold. In addition, the portable voltage detector comprises a wireless communication interface connected to the evaluation unit, which is configured to receive a setting signal to determine the warning threshold, and a voltage source connected to the sensor circuit and the communication interface, which is configured to be charged by means of a unit for inductive charging.

The portable voltage detector according to the invention allows flexible adjustment of the respectively used warning threshold via the setting signal. This makes it possible to use the same portable voltage detector for different work environments and user groups. In other words, it is no longer necessary to purchase and stock several voltage detectors for different purposes of application, which can significantly reduce the costs incurred.

The wireless communication interface may be operated using all common connecting methods for wireless data transmission.

The communication interface is preferably set up to use a Bluetooth Low Energy connection for data exchange to further reduce the current consumption of the portable voltage detector. In this way, the reliability of the portable voltage detector is also further increased at the same time, as the risk of an insufficient energy supply and thus of an unplanned functional failure is reduced.

The evaluation unit is in particular formed on a processor.

In addition, according to the invention, it is not necessary to provide an opening in the housing of the portable voltage detector via which a charging socket for charging the voltage source or a replacement of the voltage source would be provided. Instead, the portable voltage detector can be charged by simply placing it on an inductive charging surface to start a charging process. Such inductive charging surfaces are becoming increasingly common and are available worldwide.

In other words, the voltage source can be charged inductively.

For example, a service vehicle of the user may have an inductive charging surface so that the portable voltage detector can be charged while driving to or from the intended site of application and/or while driving between different sites of application.

The inductive charging can be carried out in accordance with all common inductive charging standards, for example the Qi standard of the Wireless Power Consortium or the AirFuel standard of the AirFuel Alliance. Preferably, the voltage source is set up to be inductively charged using the Qi standard.

The housing is in particular a plastic housing so that the total weight and the costs of the portable voltage detector are low.

Since a recharging of the voltage source can be realized in an easy and straightforward manner, the total capacity of the voltage source can be set to be comparatively low.

For example, the voltage source has a capacity in the range of 100 to 200 mAh. This makes it possible to design the voltage source as compact and light as possible, which also reduces the overall size and the overall weight of the voltage detector.

The warning signal emitted by the warning device may be an optical warning signal, an acoustic warning signal and/or a vibration signal.

For example, the warning device includes a lamp, in particular an LED, and/or a piezoelectric buzzer.

In one embodiment, the warning device has a vibration motor for generating the vibration signal. In other words, the vibration signal emitted by the warning device may be a haptic signal.

The warning device is preferably set up to output an optical warning signal, an acoustic warning signal and a haptic signal if the strength of an electric field detected by the sensor circuit reaches or exceeds a warning threshold.

To further reduce the complexity of the portable voltage detector, the portable voltage detector may include only a single manual control element, the single manual control element being configured to set the evaluation unit. In particular, the single manual control element is configured to set the warning threshold and/or to control an output of the evaluation unit.

For example, the single manual control element may be set up to switch off a currently emitted warning signal of the portable voltage detector upon actuation. In other words, the user can confirm in this way that the warning signal has been noticed.

In one variant, the single manual control element is set up to control whether or not the evaluation unit transmits an activating signal to the warning device in the event of a trigger. The user can thus use the single manual control element to set whether or not a warning signal is emitted at all.

If the warning device comprises several components, for example a visual display and an acoustic display, the individual manual control element can be configured to set which of the components are activated when the warning threshold is exceeded, for example only an LED or only a piezoelectric buzzer.

The individual manual control element can also be set up to adjust or replace the warning threshold stored in the evaluation unit.

The individual manual control element is preferably a push button.

The sensor circuit may comprise a sensor element for detecting electric fields and an amplifier circuit connected in series to the sensor element. The amplifier circuit serves to enable reliable evaluation even if the measurement signal generated in the sensor element is weak.

The sensor element is in particular a metal foil or a low-conductivity plastic foil, for example a metallized plastic foil.

The amplifier circuit may include a voltage divider having a preamplification function. In other words, the electric field detected via the sensor element is measured via a measuring resistor consisting of two resistors connected in parallel, an amplification element, for example an impedance converter, being provided in particular at the midpoint between these two resistors.

The voltage divider is in particular a high-impedance 1:1-voltage divider.

To generate a rectified signal from the alternating field of the displacement current, which can be easily compared with the warning threshold, the sensor circuit may comprise an operational amplifier circuit which has a low-pass filter and is arranged between the voltage divider and the evaluation unit.

In one variant, the evaluation unit is formed by a microcontroller, the microcontroller being in particular set up to switch between a sleep mode (“standby”) and an operating mode. The microcontroller can periodically switch between the sleep mode and the operating mode, the microcontroller comparing a measured value of the sensor element, which is processed by the sensor circuit, with the warning threshold and transmitting an activating signal to the warning device when the warning threshold is reached or exceeded only in the operating mode. Alternatively, the microcontroller can switch from the sleep mode to the operating mode if a comparator arranged upstream of the microcontroller detects that the warning threshold has been reached, and send a control signal to the warning device in the operating mode.

In other words, the microcontroller is in particular configured so as to be as often as possible in the sleep mode, in which the current consumption of the microcontroller is reduced. In this way, the total current consumption of the voltage detector can be reduced, so that a longer operating time without recharging can be achieved while maintaining the capacity of the voltage source.

Optionally, the sensor circuit may include an attenuation element arranged upstream of the amplifier circuit. Such a design is particularly advantageous if the portable voltage detector is to be used for work near medium and high-voltage lines, since very high displacement currents may occur at the sensor element due to the particularly high voltages to be expected there. In this case, the attenuation element ensures that the further components and parts of the sensor circuit and the evaluation unit are not damaged by these very high displacement currents. In addition, the measuring range of the sensor circuit is increased by using the attenuation element.

The attenuation element is, for example, a capacitor connected in parallel to the voltage divider.

The attenuation element may be used in different operating modes.

For example, in a first operating mode, the attenuation element may have no influence on the measurement signal generated by the sensor element, and in a second operating mode, it can attenuate the measurement signal generated by the sensor element.

In other words, if the attenuation element is intended to be used in the vicinity of electrical conductors operated at medium or high voltage, it can be set to the second operating mode to protect the further components and parts of the voltage detector from excessive electrical loads. If, on the other hand, only lower displacement currents are to be expected, for example when working in the vicinity of low-voltage systems, the attenuation element may be set to the first operating mode to allow the sensor circuit to reliably process the correspondingly lower measurement signals.

The operating mode of the attenuation element may in particular be set via the microcontroller.

In a further embodiment, the attenuation element may have a third operating mode, the attenuation element generating, in the third operating mode, a test signal which is independent of the sensor element and by means of which the operativeness of the sensor circuit can be checked.

In other words, the portable voltage detector in this case has a self-test function.

To enable the user of the voltage detector to check the operativeness of the voltage detector himself, the test signal may be adapted to be triggered via the single manual control element.

According to the invention, the object of the invention is further achieved by a system for warning of voltage hazards, comprising a portable voltage detector as previously described and a mobile device, the mobile device being configured to exchange data with the wireless communication interface of the portable voltage detector.

The mobile device is, for example, a smartphone or a tablet which can be carried by the user when the portable voltage detector is in use.

According to the invention, the portable voltage detector can be controlled via the mobile device, for example by means of an application or other control program on the mobile device.

In particular, the warning threshold may be determined via the mobile device and transmitted to the evaluation unit via the setting signal.

In addition, the mobile device may have a human-machine interface (HMI), in particular a touch-sensitive display on which at least one piece of information for operating the voltage detector can be displayed.

The information for operating the voltage detector includes, for example, the warning threshold, the currently measured strength of the electric field in the detection range of the portable voltage detector, the position of the user, the current time and/or the state of charge of the voltage source.

The mobile device may also have a logging function which stores information about the operation of the voltage detector, in particular a history of the measurement data obtained, time information, location information and/or operations of the single manual control element.

The information about the operation of the voltage detector can be stored locally on the mobile device and/or transmitted to a server via the mobile network, in particular by means of the communication interface (and optionally via the mobile device).

The separation of the portable voltage detector and the mobile device for configuring the warning threshold makes it possible to use the same voltage detector for different user groups.

For example, the warning threshold is set once using the mobile device, and then the portable voltage detector is passed on to the user, who, apart from the functions of the single manual control element, cannot influence the functioning of the current detector. This variant is particularly advantageous if the user is a layperson or an electrotechnically only instructed person, for example from emergency services.

Alternatively, the entire system comprising the portable voltage detector and the mobile device can be left to the user, so that the warning threshold of the voltage detector can also be adjusted and/or information can be read out during use. Preferably, this variant can be used if the user is an electrotechnically skilled person.

Further features and characteristics of the invention will become apparent from the following detailed description of selected embodiments, which are not be understood in a restrictive sense, and from the drawings, in which:

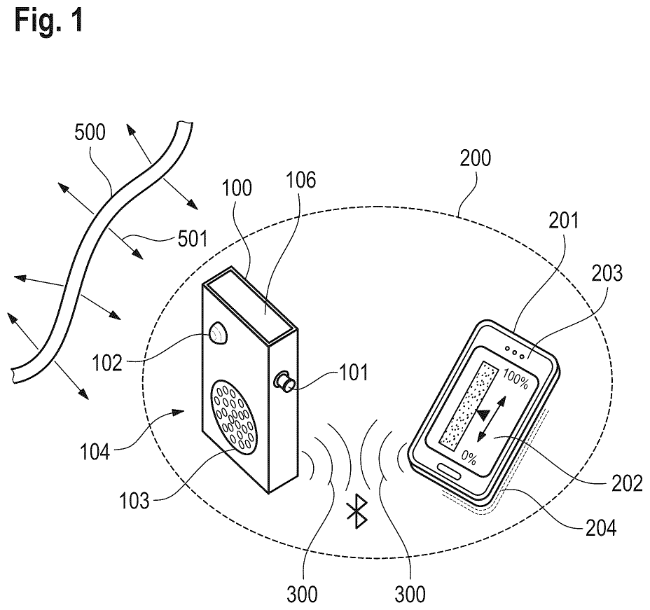

FIG. 1 shows a system for warning of voltage hazards according to the invention having a portable voltage detector according to the invention;

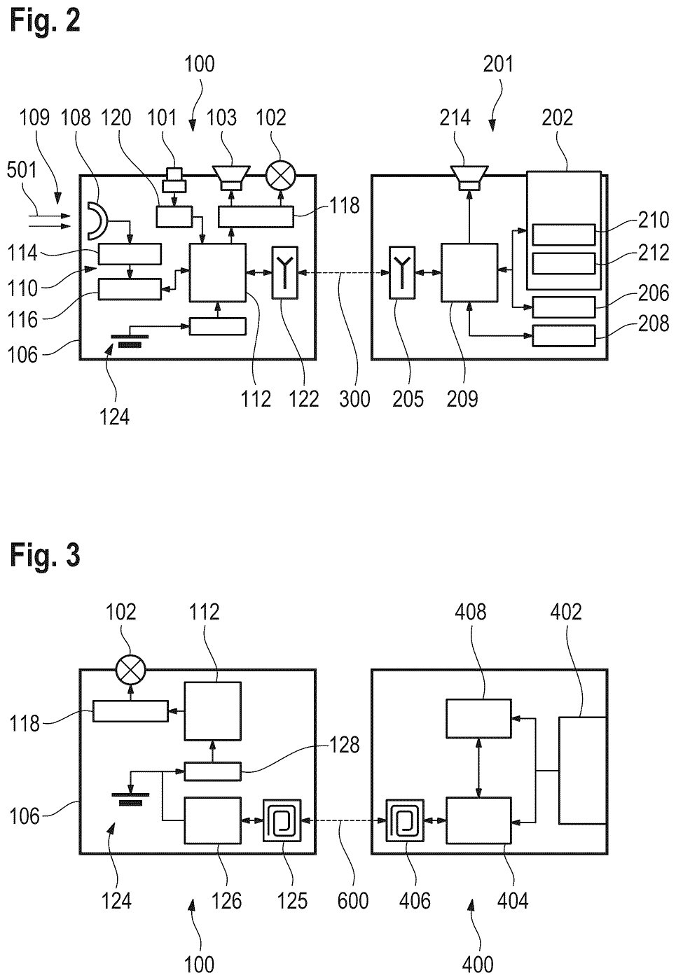

FIG. 2 shows a schematic representation of selected components of the system of FIG. 1;

FIG. 3 shows a further schematic representation of selected components of the voltage detector of FIG. 1 and an inductive charging station;

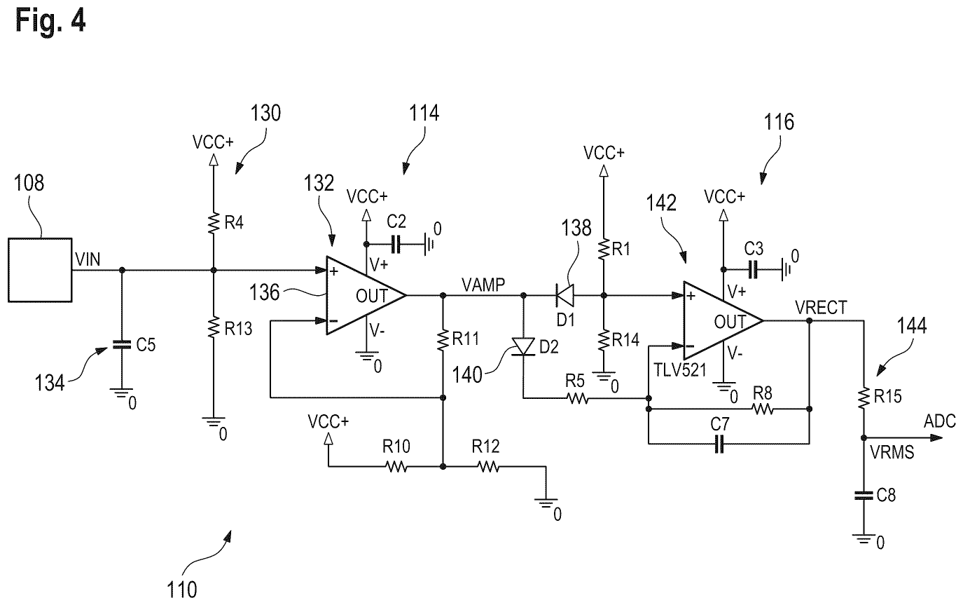

FIG. 4 shows a first embodiment of a sensor circuit of the voltage detector of FIG. 1;

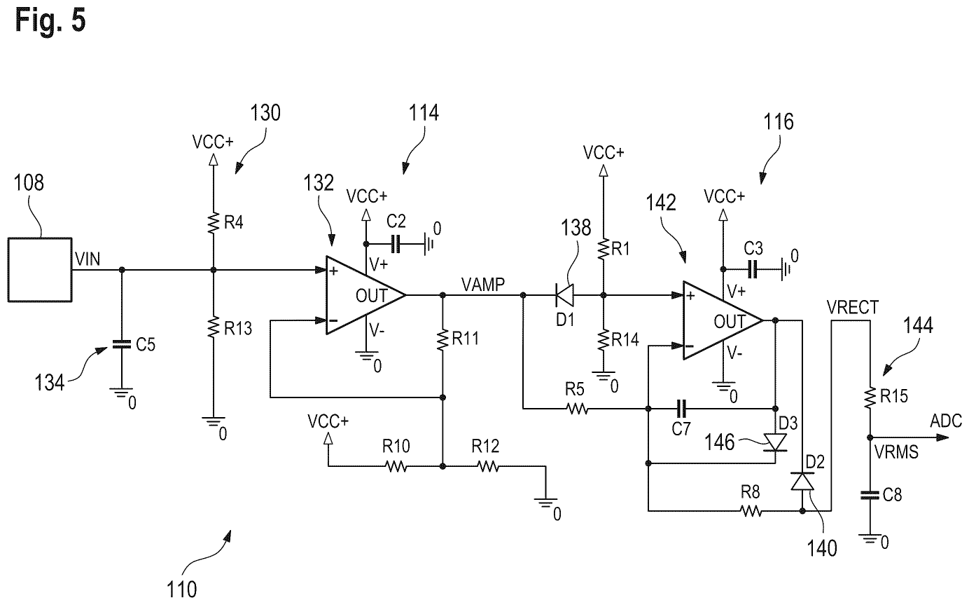

FIG. 5 shows a second embodiment of the sensor circuit;

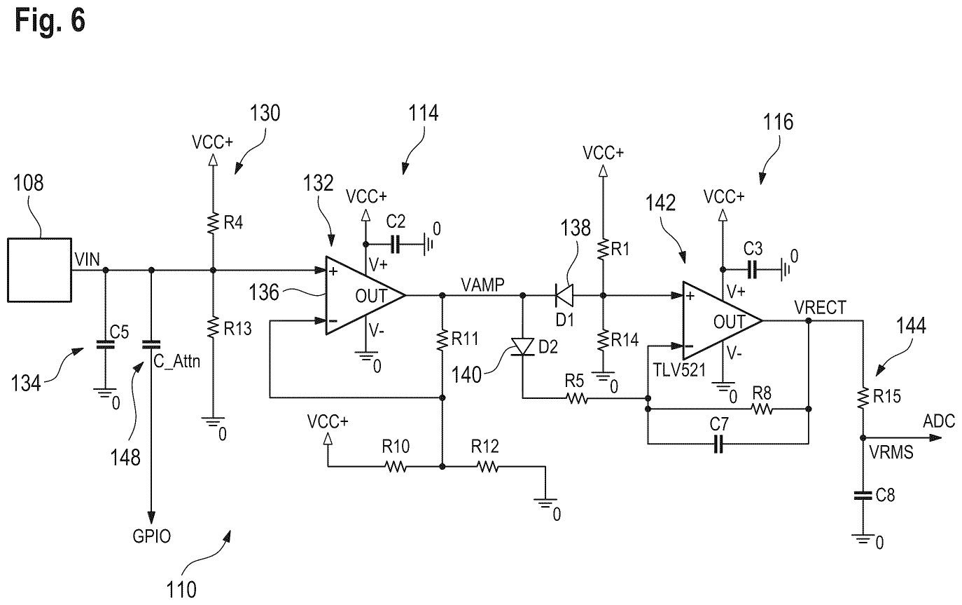

FIG. 6 shows a third embodiment of the sensor circuit; and

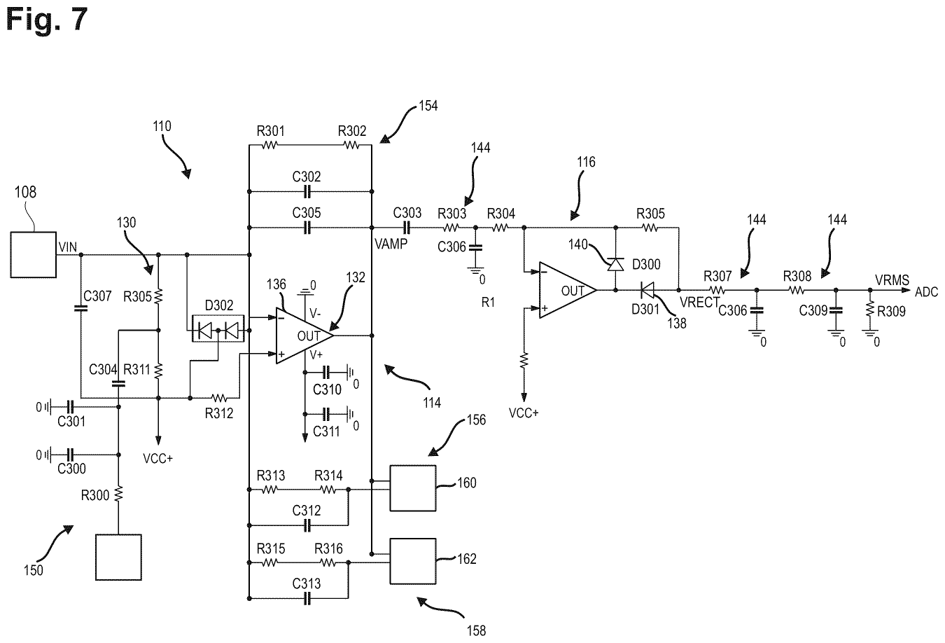

FIG. 7 shows a fourth embodiment of the sensor circuit.

FIG. 1 shows a system 200 for warning of voltage hazards according to the invention, for example for warning of an electric field 501 emanating from a high-voltage line 500, i.e. a current-carrying line.

It is understood that, instead of the high-voltage line 500, any other current-carrying electric line may also be meant, in particular also a low-voltage, medium-voltage and/or extra-high-voltage line, or another current-carrying component or a component to which a voltage is applied.

The system 200 comprises a portable voltage detector 100 and a mobile device 201.

The portable voltage detector 100 has a single manual control element 101, which in the illustrated embodiment is designed as a push button. The function of the control element 101 will be discussed in more detail later.

Furthermore, the portable voltage detector 100 comprises a visual warning indicator 102, for example an LED, and an acoustic warning indicator 103, for example a piezoelectric buzzer, which are part of a warning device 104 of the portable voltage detector 100.

The further components of the portable voltage detector 100 are accommodated in a housing 106 which, apart from the necessary loudspeaker openings for the acoustic warning indicator 103 and the openings for mounting the single manual control element 101 and the optical warning indicator 102, has no further openings so that the portable voltage detector 100 is insensitive to environmental influences such as dirt and/or water.

In the illustrated embodiment, the mobile device 201 is a smartphone. In principle, other mobile devices can also be considered as part of the system 200 according to the invention, for example a tablet.

The mobile device 201 has a human-machine interface 202, which is designed as a touch-sensitive display.

In addition, an app for controlling the portable voltage detector 100 is installed on the mobile device 201.

FIG. 2 shows selected components of the portable voltage detector 100 and of the mobile device 201.

The portable voltage detector 100 has a sensor element 108 for detecting electric fields in a detection area 109 of the portable voltage detector 100, for example for detecting the electric field 501 generated by the current flowing through the high-voltage power line 500.

The sensor element 108 is, for example, a metal foil or a slightly electrically conductive plastic foil and has a total area of a few square centimeters, for example a total area of 1 to 25 cm², in particular of 1 to 16 cm², preferably of 1 to 10 cm².

The sensor element 108 is connected to an evaluation unit 112 via a sensor circuit 110.

In the embodiment shown, the evaluation unit 112 is formed by a microcontroller which evaluates the signal received from the sensor circuit 110.

The sensor circuit 110 comprises an amplifier circuit 114 and an operational amplifier circuit 116.

A warning threshold is stored in the evaluation unit 112, i.e. in the microcontroller, and when it is exceeded, the evaluation unit 112 sends an activating signal to a trigger unit 118 of the warning device 104, on the basis of which a warning signal is output by means of the optical warning display 102 and/or the acoustic warning display 103.

The single manual control element 101 is also connected to the evaluation unit 112 via a control unit 120.

Furthermore, the voltage detector 100 has a wireless communication interface 122, by means of which a setting signal can be received which determines the warning threshold.

The components of the voltage detector 100 are supplied with electrical energy from a voltage source 124. The voltage source 124 is permanently installed inside the housing 106 and is a secondary battery having a capacity in the range of 100 to 200 mAh.

The mobile device 201 also has a wireless communication interface 205 so that the portable voltage detector 100 and the mobile device 201 can communicate with each other wirelessly.

In the embodiment shown, a Bluetooth Low Energy connection 300 is used for this purpose. It is understood that, in principle, any type of wireless communication can be used between the portable voltage detector 100 and the mobile device 201, as long as reliable data exchange is ensured.

The mobile device 201 also has a protocol module 206 and a connection module 208 for establishing a mobile data connection.

The protocol module 206 can store at least one piece of information for operating the portable voltage detector 100, which is received by the mobile device 201 by means of the wireless communication interface 205, in particular a history of the measurement data obtained in the portable voltage detector 100, time information, location information and/or operations of the single manual control element 101.

The information stored in the protocol module 206 regarding the operation of the portable voltage detector 100 can be used after an accident to analyze it to clarify the causes of the accident and, based on the results of this analysis, to take measures to further increase occupational safety in the future.

A display module 210 can be used to display at least some of the information for operating the portable voltage detector 100 on the human-machine interface 202.

User inputs made via the human-machine interface 202 can be evaluated via a configuration module 212.

The connection module 208 can be used to transmit any information stored in the protocol module 206 to a server via a mobile data connection.

Furthermore, an acoustic output means 214 is provided. In addition to the components of the warning device 104 of the portable voltage detector 100, a warning signal can be emitted via the acoustic output means 214 if an exceeding of the warning threshold is detected in the microprocessor of the portable voltage detector 100.

The mobile device 201 can be set up to trigger a vibration alarm if an exceeding of the warning threshold is determined in the evaluation unit 112 of the portable voltage detector 100, as indicated by the dashed lines 204 in FIG. 1.

The various components and modules of the mobile device 201 are connected to a processor 209 which is set up to control the functions of the individual components and modules of the mobile device 201.

The system according to the invention 200 is characterized by the fact that the portable voltage detector 100 can optionally be used together with the mobile device 201 or individually.

In particular, when the system 200 according to the invention is used by trained specialist personnel as an additional means of increasing occupational safety, the portable voltage detector 100 is used along with the mobile device 201. In this way, the specialist personnel on site can adjust the warning threshold as required in a situation-optimized manner, for example to avoid unnecessary false alarms due to a warning threshold which is too low.

If, on the other hand, the portable voltage detector 100 is used by untrained personnel, for example laypersons or electrotechnically only instructed persons, such as emergency services, the warning threshold can be determined centrally using the mobile device 201, and the portable voltage detector 100 can be used individually. In this case, the user has no possibility to adjust the warning threshold independently and thus cannot set the warning threshold too low due to an incorrect assessment of the hazard.

The system 200 according to the invention is thus suitable for different user groups without the need to provide different types of portable voltage detectors 100.

FIG. 3 shows a further schematic representation of the portable voltage detector 100 in connection with a unit 400 for inductive charging.

The unit 400 for inductive charging is supplied with electrical energy via a power unit 402 and has a transmitter module 404 and a sending coil 406.

The unit 400 for inductive charging is controlled by a processor 408, which is connected to the power unit 402 and the transmitter module 404.

The portable voltage detector 100 has a receiving coil 125 and a receiving module 126 with charging control.

A wireless charging connection 600 can be established between the portable voltage detector 100 and the unit 400 for inductive charging between the sending coil 406 and the receiving coil 125, in particular a wireless charging connection according to the Qi standard.

The receiving module 126 is connected to the voltage source 124 and to a monitoring module 128 for monitoring the state of charge of the voltage source 124.

The evaluation unit 112 is also connected to the monitoring module 128.

Due to the charging of the portable voltage detector 100 using a wireless charging technology, it is possible that the housing 106 does not need to have an additional opening for a charging interface. This increases resistance to environmental influences such as moisture and/or dirt. It also makes the portable voltage detector 100 easier to use.

FIG. 4 shows a circuit diagram of a first embodiment of the sensor circuit 110.

In this embodiment, the amplifier circuit 114 is formed by a voltage divider 130 having an amplifier circuit 132.

The voltage divider 130 is a high-impedance 1:1-voltage divider, resistors connected in parallel being used, which are designated in FIGS. 4 as R4 and R13 and which, for example, have a resistance of 2.0 MΩ or more.

The voltage divider 130 therefore measures the current determined by the sensor element 108 as a measurement signal. The measurement signal determined by the sensor element 108 also has a voltage VIN.

A upstream capacitor 134 is provided between the voltage divider 130 and the sensor element 108, the capacitance of which can be used to determine an attenuation factor for the measurement signal of the sensor element 108.

The measurement signal represents a bipolar signal due to the detection of the change in the electric field 501 in the detection area 109. The sensor circuit 110 serves, among other things, to convert the output signal of the sensor circuit 110 into a unipolar signal to simplify the comparison of this unipolar signal with the warning threshold.

The voltage V_{IN} is pre-amplified to a voltage V_{AMP} by means of an impedance converter 136 of the amplifier circuit 132, which is connected to the midpoint of the voltage divider 130,.

In principle, this signal could already be used by means of an analog-digital converter (ADC) of the evaluation unit 112, i.e. the microcontroller, for comparison with the warning threshold stored in the evaluation unit 112.

In particular, a post-amplification is provided, which in the present case comprises the resistors R10, R11 and R12, via which the signal fed back into the impedance converter 136 is post-amplified, which is based on the output signal of the impedance converter 136.

In the embodiment shown in FIG. 4, however, the operational amplifier circuit 116 is additionally provided, which functions as a rectifier.

In this circuit, the output signal of the amplifier circuit 114 is rectified via diodes 138 and 140 (voltage V_{RECT}), amplified by means of a second impedance converter 142, and filtered via a low-pass filter 144 (“RC element”) to obtain an output signal having a voltage V_{RMS}.

The embodiment of the sensor circuit 110 shown in FIG. 4 generates an output signal which is transmitted to the ADC of the evaluation unit 112, i.e. the microcontroller. The output signal is inverted with respect to the measurement signal generated by the sensor element 108 and has a voltage in the range between half the supply voltage V_{CC} and ground.

The limitation to half the supply voltage makes it possible to double the resolution in the ADC of the evaluation unit 112 compared to an amplified measurement signal having a voltage V_{AMP} that is tapped directly after the impedance converter 136.

In addition, it is possible to draw conclusions about electrical defects in the sensor circuit 110 if the voltage deviates from half the supply voltage V_{CC} in the quiescent state of the sensor circuit 110, i.e. when there is no electric field 501 in the detection area 109. In this way, malfunctions of the sensor circuit 110 can be reliably detected.

Overall, the sensor circuit 110 is characterized by an analog, i.e. hardware-related, effective value formation. In other words, the measurement signal emanating from the sensor element 108 is already processed by means of the components of the sensor circuit 110 before it is transmitted to the evaluation unit 112. In this way, the necessary activity of the evaluation unit 112 can be limited to a necessary minimum, which leads to lower energy consumption and thus to a longer operating time and increased reliability of the portable voltage detector 100.

FIG. 5 shows a second embodiment of the sensor circuit 110.

The second embodiment corresponds substantially to the first embodiment, so that only the differences will be discussed below. The same reference numerals are used for the same components, and reference is made to the above explanations.

In the second embodiment, a third diode 146 is present, the direction of passage of which is opposite to that of the diode 140 and which is used in the rectification of the output signal of the amplifier circuit 114. The voltage drop across the diode 140 is thus compensated for, and the sensitivity of the amplifier circuit 114 is therefore improved.

FIG. 6 shows a third embodiment of the sensor circuit 110.

The third embodiment corresponds substantially to the first embodiment, so that only the differences will be discussed below. The same reference numerals are used for the same components, and reference is made to the above explanations.

In the third embodiment, an additional attenuation element 148 is arranged upstream of the voltage divider 130 and the amplifier circuit 114.

The attenuation element 148 is connected to an I/O pin of the microcontroller, designated as GPIO in FIG. 6, and comprises a capacitor which can be set via a signal from the evaluation unit 112. In other words, the attenuation element 148 has several operating modes.

In a first operating mode, the attenuation element 148 has no influence on the measurement signal supplied by the sensor element 108. This can be achieved by switching the I/O pin of the evaluation unit 112 to high impedance, thus preventing the current flow across the capacitor of the attenuation element 148.

In a second operating mode, the attenuation element 148 attenuates the measurement signal supplied by the sensor element 108 by lowering the resistance at the I/O pin of the evaluation unit 112, i.e. of the microcontroller, to a desired level. Thus, part of the displacement current detected by the sensor element 108 flows off via the attenuation element 148 and not via the voltage divider 130.

The attenuation element 148 can thus serve as a protective component for the other parts and components of the sensor circuit 110 by avoiding displacement currents which are above the currents that the other parts and components can withstand.

Alternatively or additionally, the attenuation element 148 serves to increase the measuring range of the sensor circuit 110.

For this purpose, the attenuation element 148 can also comprise several capacitors connected in parallel, which can each be activated via an I/O pin of the evaluation unit 112 to be able to realize a customized attenuation effect.

In a third operating mode, the attenuation element 148 generates a test signal which is independent of the sensor element 108 and by means of which the operativeness of the sensor circuit 110 can be checked.

In this operating mode, a periodically recurring pulse-shaped current signal is fed from the evaluation unit 112 via the I/O pin into the attenuation element 148.

In this way, an alternating current signal is generated which is detected by the voltage divider 130 and amplified, rectified and filtered by the amplifier circuit 114 and the operational amplifier circuit 116.

The output signal generated in this case by the sensor circuit 110 can be checked and evaluated in the evaluation unit 112 by comparison with an expected measurement signal curve. Thus, in this embodiment, the portable voltage detector 100 has a self-test operativeness without the need to install further parts or components.

If a deviation from the expected measurement signal curve is detected, the evaluation unit 112 is set up to send an activating signal to the warning device 104 so that it emits a warning signal.

Preferably, the self-test can also be started by the user by means of the single manual control element 101.

FIG. 7 shows a fourth embodiment of the sensor circuit 110.

The fourth embodiment corresponds substantially to the previous embodiments, so that only the differences will be discussed in the following. The same reference numerals are used for the same components, and reference is made to the above explanations.

In the fourth embodiment, the voltage divider 130 is connected to the sensor element 108 and to the amplifier circuit 114 at an end-side connection point and not at the midpoint.

Instead, a test circuit 150 is connected to the midpoint of the voltage divider 130, via which a test signal from a test microcontroller 152 can be fed into the circuit arrangement 110.

The resistor R300 and the capacitors C300, C301 and C304 shown in FIG. 7 serve to filter the test signal supplied by the test microcontroller 152 and to adjust the level thereof.

In the fourth embodiment, the amplifier circuit 114 has a three-stage level adjustment with a first control stage 154, a second control stage 156 and a third control stage 158.

The first control stage 154 represents a permanently installed feedback path and comprises two resistors R301 and R302 and two respective capacitors C302 and C305, which are connected in parallel to the resistors R301 and R302 and are also connected in parallel to each other.

The second control stage 156 includes an integrated circuit 160, two resistors R313 and R314, and one capacitor C312 connected in parallel to the resistors R313 and R314.

The third control stage 158 is designed in the same way as the second control stage 158 and includes an integrated circuit 162, two resistors R315 and R316, and one capacitor C313 connected in parallel to the resistors R315 and R316.

Depending on how much amplification is desired through the amplifier circuit 114, the first control stage 154, the second control stage 156 or the third control stage 158 is active to achieve the greatest possible dynamic range for the sensor circuit 110.

If the first control stage 154 is active, the amplification through the amplifier circuit 114 is the greatest. If the second control stage 156 is activated by means of the integrated circuit 160, the amplification by the amplifier circuit 114 is attenuated. If the third control stage 158 is activated by means of the integrated circuit 162, the amplification by the amplifier circuit 114 is attenuated even further than is the case in the second control stage 156.

In particular, the amplification of the amplifier circuit 114 is attenuated by a factor of up to 5 compared to the amplification in the first control stage 154 when the second control stage 156 is active.

If the third control stage 158 is active, the amplification of the amplifier circuit 114 is attenuated in particular by a factor of up to 15 compared to the amplification in the first control stage 154.

The output signal of the amplifier circuit 114 is DC-decoupled by means of a capacitor C303 and supplied to the operational amplifier circuit 116, which also acts as a rectifier by means of the diodes 138 and 140.

The operational amplifier circuit 116 comprises an inverting amplifier the positive output of which is permanently connected to the positive reference potential V_{CC}.

The diodes 138 and 140 are designed such that the diode 138 is conductive for positive half-waves of the input signal reaching the operational amplifier circuit 116, while the diode 140 is conductive for negative half-waves of the input signal.

An amplification factor of the operational amplifier circuit 116 is thus determined by selecting the resistors R304 and R305.

After filtering via the low-pass filters 144 arranged downstream of the operational amplifier circuit 116, a quasi-DC potential is generated, which is supplied to the analog-digital converter (ADC) of the evaluation unit 112 and is used for comparison with the warning threshold stored in the evaluation unit 112.

Overall, the system 200 according to the invention is characterized by flexible use for different user groups, while at the same time providing reliable detection of electric fields. The portable voltage detector 100 is also particularly robust and equipped with a long-lasting power supply.

1. A portable voltage detector, comprising a housing (106),
a sensor circuit (110) accommodated in the housing (106) for detecting electric fields (501) within a detection range (109) of the portable voltage detector (100),
an evaluation unit (112) accommodated in the housing (106) for evaluating the detected electric fields, the evaluation unit (112) being connected to the sensor circuit (110),
a warning device (104) which is connected to the evaluation unit (112) and set up to output a warning signal if the strength of an electric field (501) detected by the sensor circuit (110) reaches or exceeds a warning threshold,
a wireless communication interface (122) which is connected to the evaluation unit (112) and configured to receive a setting signal for determining the warning threshold, and
a voltage source (124) connected to the sensor circuit (110) and to the communication interface (122), the voltage source (124) being configured to be charged by means of a unit (400) for inductive charging.

2. The portable voltage detector according to claim 1, the portable voltage detector (100) having only a single manual control element (101), the single manual control element (101) being configured to set the evaluation unit (112), in particular to set the warning threshold and/or to control an output of the evaluation unit (112).

3. The portable voltage detector according to claim 1, the sensor circuit (110) comprising a sensor element (108) for detecting electric fields (501) and an amplifier circuit (114) connected in series to the sensor element (108).

4. The portable voltage detector according to claim 3, the amplifier circuit (114) comprising a voltage divider (130) having a preamplification function.

5. The portable voltage detector according to claim 4, the sensor circuit (110) comprising an operational amplifier circuit (116) which has a low-pass filter (144) and is arranged between the voltage divider (130) and the evaluation unit (112).

6. The portable voltage detector according to claim 1, the evaluation unit (112) being formed by a microcontroller and the microcontroller being in particular set up to switch between a sleep mode and an operating mode, the microcontroller either
switching periodically between the sleep mode and the operating mode and, only in the operating mode, comparing a measured value of the sensor element (108), which is processed by the sensor circuit (110), with the warning threshold and, when the warning threshold is reached or exceeded, transmitting an activating signal to the warning device (104), or
the microcontroller switching from the sleep mode to the operating mode if a comparator arranged upstream of the microcontroller determines that the warning threshold has been reached, and sending an activating signal to the warning device (104) in the operating mode.

7. The portable voltage detector according to claim 3, the sensor circuit (110) comprising an attenuation element (148) which is connected upstream of the amplifier circuit (132).

8. The portable voltage detector according to claim 7, the attenuation element (148) having no influence on the measurement signal generated by the sensor element (108) in a first operating mode and attenuating the measurement signal generated by the sensor element (108) in a second operating mode.

9. The portable voltage detector according to claim 7, the attenuation element (108) generating, in a third operating mode, a test signal which is independent of the sensor element (108) and by means of which the operativeness of the sensor circuit (110) can be checked.

10. A system for warning of voltage hazards comprising a portable voltage detector (100) according to claim 1 and a mobile device (201), the mobile device (201) being configured to exchange data with the wireless communication interface (122) of the portable voltage detector (100).
